(19) United States
(12) Patent Application Publication
(10) Pub. No.: US 2007/0278539 A1
(43) Pub. Date: Dec. 6, 2007

(54) Junction field effect transistor and method for manufacture

(75) Inventors: Mark Victor Dyson, Singapore (SG); Nace Rossi, Singapore (SG); Ranbir Singh, Singapore (SG)

Correspondence Address: PRIEST & GOLDSTEIN, PLLC, 5015 SOUTHPARK DRIVE, SUITE 230, DURHAM, NC, 27713, US

(73) Assignee: Agere Systems Inc., Allentown, PA (US)

(21) Appl. No.: 11/446,016

(22) Filed: Jun. 2, 2006

(51) Int. Cl. H01L 29/76; H01L 29/808; H01L 21/337

(52) U.S. Cl. 257/256; 438/186; 438/194; 257/274

(57) ABSTRACT

A semiconductor device is described that operates as an improved junction field effect transistor (JFET). A bipolar transistor with a collector region, a base region, an emitter region, a first base contact, and a second base contact insulated from the first base contact, has the base region lightly doped to about a 1E16 to 5E17 atoms/cm³ doping level. A connection is provided between the emitter region and the collector region to act as a JFET gate contact for the bipolar transistor. The semiconductor device operates as an improved JFET with the first base contact being a drain contact and the second base contact being a source contact. A method for manufacture of an improved JFET on a chip containing conventional bipolar devices is also described. The improved JFET is shown being used with a write head in a disk drive system for providing electrostatic discharge protection.

### FIELD OF INVENTION

The present invention relates generally to junction field effect transistors (JFETs), and more particularly, to an improved JFET, use of the improved JFET for electrostatic discharge protection of a magnetic transducer, and advantageous methods for manufacture of the improved JFET.

### BACKGROUND OF INVENTION

A junction field effect transistor (JFET) may be considered a voltage-controlled resistor. The resistive element is usually a bar of silicon. For a P-channel JFET, this bar is a P-type material and is sandwiched between two layers of N-type material. The two layers of N-type material are electrically connected together and are called the gate. One end of the P-type bar is the source terminal and the other end is the drain terminal. Current is injected into the P-type bar from the source terminal and collected at the drain terminal. A problem with a conventional JFET for use in electrostatic discharge (ESD) protection is the large parasitic capacitance which it possesses. This capacitance may degrade performance in certain applications, such as digital magnetic recording systems.

Digital magnetic recording stores digital data by use of a magnetic transducer or write head to modulate a magnetic flux pattern in a magnetic medium. During the storing process, an electric current in the write head is modulated based on the digital data to be written. The head is positioned over magnetic material in the shape of a circular disk. The disk rotates rapidly and data is written in circular tracks. The electric current, driven from an amplifier or preamplifier circuit to the write head, modulates the magnetic flux pattern in the medium of the disk. The medium used is such that the flux pattern is retained in the medium after the electric current is turned off in the write head, thus providing data storage.

During a read process, a magnetic transducer or read head is positioned over the medium following the tracks, but now the magnetic flux pattern in the medium induces a current in the read head. This current is then received in an amplifier or preamplifier and processed to recover the written data. The reading of the signals from the read head typically employs an analog signal path including filtering, amplification, and timing acquisition stages.

Due to the close proximity of the read and write heads to the storage medium and due to environmental conditions, a charge may build up in a high density disk (HDD) drive and expose the read/write heads and drive circuitry to an electrostatic discharge (ESD). Due to the sensitivity of the read and write heads and closely coupled preamplifier, an ESD may cause permanent damage. Prior techniques to limit or prevent ESDs include use of a conventional JFET, a depletion mode transistor, or the like, to bleed charge to limit an ESD.

### SUMMARY OF INVENTION

Among its several aspects, the present invention recognizes that prior techniques, including a depletion mode transistor to bleed charge, for example, may severely degrade the performance of newer generations of read/write systems, and that there is a need for a device architecture, such as an improved JFET (iJFET), that offers high performance with low parasitic capacitance that can be easily manufactured. It is a further recognized that it is desirable to integrate the improved JFET in a manufacturing process that is common to that used for manufacturing an amplifier or preamplifier which interfaces with at least one magnetic transducer. It is a further aspect of the present invention to connect the improved JFET in a circuit such that excess charge can be bled away from a connected magnetic transducer, such as, a read or write head, to protect the read or write head from electrostatic discharge.

An embodiment according to one aspect of the present invention includes a semiconductor device having a silicon substrate with a buried implant region. A base region is located over the buried implant region, the base region doped to have a dopant level sufficiently reduced to allow the base region to be pinched-off upon application of a first gate voltage. A source lead is in contact with the base region. A drain lead is in contact with the base region and spaced apart from the source lead. A gate region placed over the base region between the source lead and the drain lead, apart from the source lead and the drain lead, and in contact with the base region. A gate lead is in contact with the buried implant region and in contact with the gate region. With a second gate voltage applied to the gate lead a conduction channel is formed in the base region between the source lead and the drain lead and with the first gate voltage applied to the gate lead, depletion regions form in the base region that pinch-off the conduction channel between the source lead and the drain lead.

Another embodiment according to a further aspect of the present invention addresses a semiconductor device with a silicon substrate with an implanted collector region, the collector region having a first connection point. A base region is located over the buried implant region and the base region has a dopant level low enough to allow the base region to be pinched-off upon application of a first gate voltage. A source connection point is provided on the base region. A drain connection point is provided on the base region and spaced apart from the source connection point. A gate connection point is provided on the base region, the gate connection point in contact with the first connection point and adapted for coupling to a control signal. The gate connection point is placed between the source connection point and the drain connection point. With a control signal applying the first gate voltage, the gate region is pinched-off.

Another embodiment according to another aspect of the present invention addresses a method of manufacturing a semiconductor device. A buried implant region is formed in a silicon substrate with a first connection point. A base region is formed over the buried implant region with a dopant level low enough to allow the base region to be pinched-off upon application of a first gate voltage. A source connection point is formed on the base region. A drain connection point is formed on the base region spaced apart from the source connection point. A gate connection point is formed on the base region, in contact with the first connection point, and adapted for coupling to a control signal. The gate connection point is placed on the base region between the source connection point and the drain connection point.

A more complete understanding of the present invention, as well as other features and advantages of the invention, will be apparent from the following detailed description, the accompanying drawings, and the claims.

### BRIEF DESCRIPTION OF DRAWINGS

FIG. 1A illustrates a first read/write subsystem for electrostatic discharge protection in accordance with an embodiment of the present invention;

FIG. 1B illustrates a second read/write subsystem for electrostatic discharge protection in accordance with another embodiment of the present invention;

FIG. 2 illustrates an advantageous complementary metal oxide semiconductor (CMOS) bipolar device fabrication process having a first CMOS fabrication step, a first bipolar fabrication step, a second bipolar fabrication step, a third bipolar fabrication step, and a second CMOS fabrication step, for the manufacture of an improved JFET (iJFET) of FIG. 1A or 1B in accordance with an embodiment of the present invention;

FIG. 3 illustrates a first exemplary CMOS material cut-away view showing the material layers resulting from the first CMOS fabrication step of FIG. 2 for the manufacture of the iJFET in accordance with the present invention;

FIG. 4A illustrates a cut-away view showing the material layers resulting from a portion of the first bipolar fabrication step of FIG. 2 in accordance with the present invention;

FIG. 4B illustrates a first exemplary CMOS/bipolar material cut-away magnified view showing the material layers resulting from the first bipolar fabrication step of FIG. 2 for the manufacture of the iJFET in accordance with the present invention;

FIG. 5 illustrates a second exemplary CMOS/bipolar material cut-away magnified view showing the material layers resulting from the second bipolar fabrication step of FIG. 2 for the manufacture of the iJFET in accordance with the present invention;

FIG. 6A illustrates a third exemplary CMOS/bipolar material cut-away magnified view of the iJFET showing the material layers resulting from the third bipolar fabrication step of FIG. 2 for the manufacture of the iJFET in accordance with the present invention;

FIG. 6B illustrates the iJFET device with exemplary connections and no bias depletion regions in accordance with the present invention;

FIG. 6C illustrates the iJFET device with exemplary connections and biased depletion regions in accordance with the present invention; and

FIG. 7 illustrates a fourth exemplary CMOS/bipolar material cut-away view showing the material layers resulting from the second CMOS fabrication step of FIG. 2 for the manufacture of the iJFET in accordance with the present invention.

### DETAILED DESCRIPTION

The present invention will now be described more fully with reference to the accompanying drawings, in which several embodiments and various aspects of the invention are shown. This invention may, however, be embodied in various forms and should not be construed as being limited to the embodiments set forth herein. Rather, these embodiments are provided so that this disclosure will be thorough and complete, and will fully convey the scope of the invention to those skilled in the art.

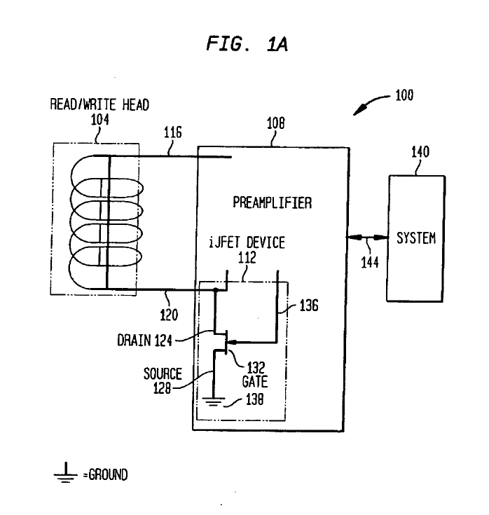

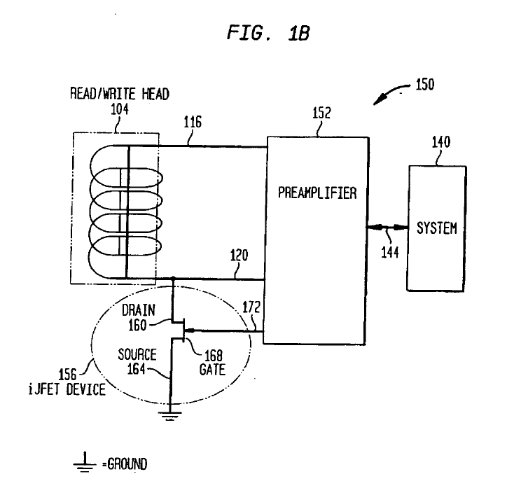

FIG. 1A illustrates a first read/write subsystem 100 for electrostatic discharge (ESD) protection in accordance with the present invention. The first read/write subsystem 100 contains a magnetic transducer read/write head assembly 104, a preamplifier chip 108, and an improved junction field effect transistor (iJFET) 112. For example, the magnetic transducer read/write head assembly 104 may include the use of a magnetoresistive technology. The iJFET 112 is advantageously manufactured on the preamplifier chip 108 using a process such as the one described in more detail below. The read/write head assembly 104 is connected to the preamplifier chip 108 using a number of wires as illustrated by signal paths 116 and 120. The iJFET 112 connects drain contact 124 to signal path 120, source contact 128 to ground, and gate contact 132 to control signal 136. The iJFET 112 is in a conductive state when the control signal 136 applies a zero voltage to the gate contact 132. The iJFET 112 is not in a conductive state when the control signal 136 applies a voltage to the gate contact 132 which actives the iJFET 112 to a high impedance state between the drain contact 124 and the source contact 128. When the disk drive is off or not reading or writing data, the iJFET 112 is kept off in a conductive state providing a current bleed off path to ground 138 protecting the first read/write subsystem 100 from ESDs. When the disk drive is operating to read or write data, the iJFET 112 is turned on in a high impedance state allowing the read or write operation to occur in a normal fashion. The preamplifier chip 108 connects to a system 140 over a cable 144 to obtain power for the first read/write subsystem 100 and to communicate data and control information. It is noted that the magnetic transducer read/write head assembly 104 is exemplary and the present invention may be suitably applied to a sensor or the like where accumulating electrostatic charge needs to bleed off slowly.

FIG. 1B illustrates a second read/write subsystem 150 for electrostatic discharge protection in accordance with the present invention. The second read/write subsystem 150 contains read/write head 104, a preamplifier chip 152, and a second iJFET 156. The iJFET 156 is manufactured as a discrete device which may be mounted with or close to the read/write head 104. A drain contact 160 is connected to signal path 120, a source contact 164 is connected to ground, and a gate contact 168 is connected to a control signal 172.

The control signals 136 and 172 generated in preamplifiers 108 and 152 may be held at a zero or near zero voltage level to keep the iJFETs 112 and 156, respectively, in the conductive state. The zero voltage state is also the voltage the control signals 136 and 172 drift to when power is not applied, thereby keeping the iJFETs 112 and 156, respectively, in the conductive protective state. Power to the first read/write subsystem 100 or the second read/write subsystem 150 in FIG. 1B, for example, may not be available or may be lost, for example, when cable 144 is not connected or becomes disconnected. To activate the iJFETs 112 and 156, control signals 136 and 172 each of a negative voltage, for example, −3 volts, may be used to turn on the iJFETs 112 and 156, respectively, to a high impedance state.

In the following detailed description, an exemplary set of fabrication steps and sub-steps are described. It is realized that variations in manufacturing technology may require variations to the fabrication steps illustrated. For example, some steps may be omitted, additional steps may be added, or the sequence of steps may be varied without departing from the invention. It will also be recognized that the figures are not to scale and various elements may be highlighted and at a different scale than other elements in a figure for illustrative purposes.

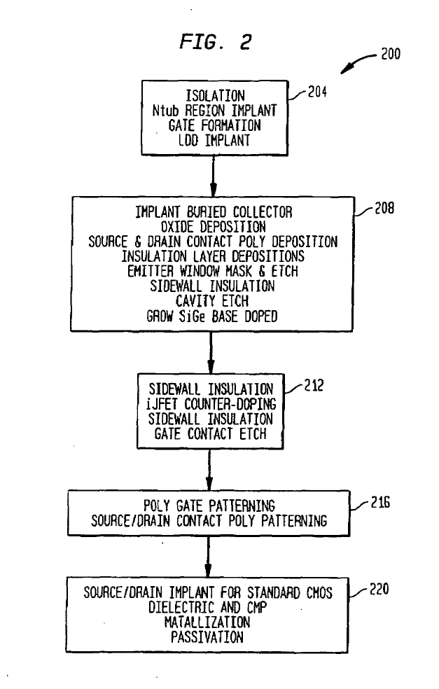

FIG. 2 illustrates an advantageous complementary metal oxide semiconductor (CMOS) bipolar device fabrication process 200 having a first CMOS fabrication step 204, a first bipolar fabrication step 208, a second bipolar fabrication step 212, a third bipolar fabrication step 216, and a second CMOS fabrication step 220, for the manufacture of the iJFETs 112 of FIG. 1A and 156 in FIG. 1B in accordance with the present invention. The CMOS bipolar fabrication process 200 begins with a first CMOS fabrication step 204 to create a substrate for the iJFET. A bipolar process, such as a silicon germanium (SiGe) process, follows with a first bipolar fabrication step 208 to create a bipolar base that is to be used in the iJFET. A second bipolar fabrication step 212 reconfigures the bipolar base as a depletion base for the iJFET. A third bipolar fabrication step 216 completes the bipolar process steps and is followed by a second CMOS fabrication step 220 which provides an advantageous wiring connection for the iJFET.

The first CMOS fabrication step 204 consists of a number of general sub-steps for manufacturing CMOS devices. These general sub-steps may include, for example, an insulation step, an N region implant (Ntub) step, followed by a gate formation process and a lightly doped drain (LDD) step.

The first bipolar fabrication step 208 consists of a number of general sub-steps. These general sub-steps may include steps to implant a buried collector, deposit oxide, deposit polysilicon, deposit insulation layers, mask and etch steps to form an emitter window, deposit sidewall insulation layers, etch a cavity, and a step to grow a doped SiGe base in the etched cavity.

A second bipolar fabrication step 212 is used to reconfigure a bipolar device into a depletion iJFET by providing a sidewall insulation layer, advantageously counter-doping a base p-body region of the bipolar device, providing another sidewall insulation layer, and a gate contact etch. The sidewall insulation steps form a double spacer isolation layer that provides insulation between drain and source connections of the device. It is noted that the iJFET counter-doping step may be placed anywhere from base deposition to gate deposition in the emitter window.

A third bipolar fabrication step 216 is used to form the gate polysilicon (poly) of the device, termed a poly gate patterning step, and to prepare the source and drain configurations on the device, termed a source/drain contact poly patterning step. The patterning is accomplished using conventional etch chemistries.

A second CMOS fabrication step 220 is used for source drain implant, dielectric deposition and chemical mechanical planarization (CMP), metallization providing advantageous connections between the gates of the iJFET, and passivation.

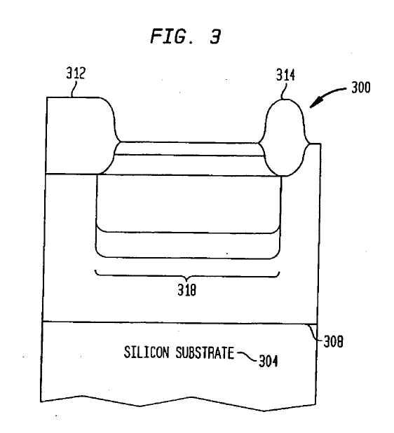

FIG. 3 illustrates a first exemplary CMOS material cut-away view 300 showing the material layers resulting from the first CMOS fabrication step 204 of FIG. 2 for the manufacture of the iJFET in accordance with an embodiment of the present invention. The first CMOS fabrication step 204 is characterized by a number of general steps. A silicon substrate 304 is prepared with a P+epitaxy layer 308. Insulation barriers between other devices on chip, such as insulation barriers 312 and 314, are provided by a local oxidation of silicon (LOCOS). Other insulation techniques, such as, shallow trench isolation (STI) can also be used. An Ntub region 318 is formed next. If other devices are included on chip, such as a preamplifier and logic devices, then gate formation and a lightly doped drain implant steps are accomplished next. If discrete iJFETs in a bipolar only chip are being manufactured, the gate formation and lightly doped drain implant steps may be excluded.

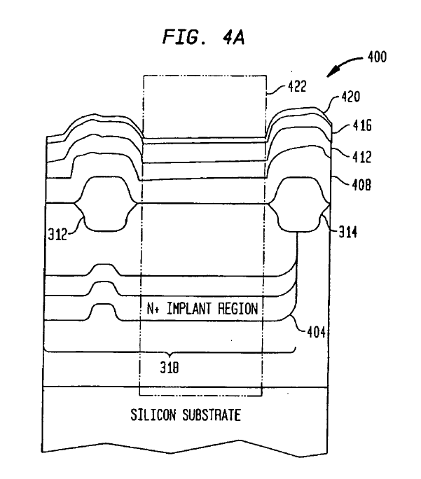

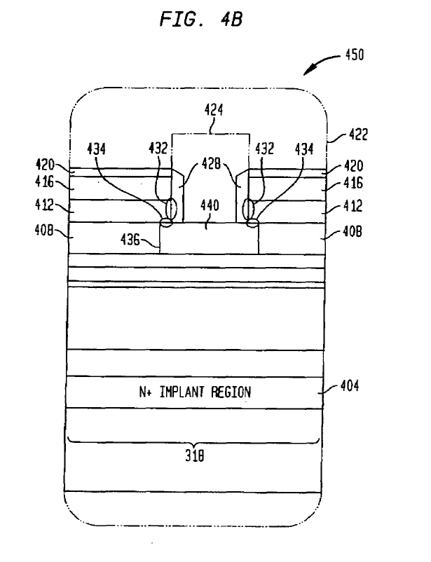

FIG. 4 illustrates a first exemplary CMOS/bipolar material cut-away view 400 showing the material layers resulting from the first bipolar fabrication step 208 of FIG. 2 for the manufacture of the iJFET in accordance with an embodiment of the present invention. The first bipolar fabrication step 208 is characterized by a number of general steps. An epi-free buried N+ implant region 404 is formed by using a high-energy implantation process, as is generally known in the art. The N+ implant region 404 is used as a collector region in a bipolar device and as a gate region in the iJFET, as described in further detail below. An insulating oxide layer 408 is deposited next followed by a deposition of an amorphous or a polysilicon film. In subsequent text, this film is referred to as silicon layer 412. The silicon layer 412 forms the extrinsic source and drain base for the iJFET device as well as base contacts for the bipolar device. An insulation layer 416, for example, comprising silicon nitride or silicon oxy-nitride, and a tetraethyl orthosilicate (TEOS) oxide layer 420 are deposited on top of the silicon layer 412 to provide isolation between the silicon layer 412 and another silicon layer that will be deposited in a later step, as described below. A section 422 of silicon is magnified in FIG. 4B to better illustrate the additional steps in the process.

In FIG. 4B section 422, an emitter window 424 is opened through the insulation layers 416 and 420 and the silicon layer 412 by masking and etching. A thin sidewall insulation layer 428 is then formed in the emitter window 424 to limit growth on the edges 432 of the silicon layer 412 due to later processing steps which deposit epitaxial (epi) silicon in a formed cavity 436. Using hydrofluoric acid (HF), the insulating oxide layer 408 is etched away to form the cavity 436. A silicon geranium (SiGe) base layer segment 440 is selectively grown in the cavity 436 and fills the lateral gaps to form a good contact, such as contact points 434, with the silicon layer 412. The base layer segment 440 is heavily doped with p⁺ boron to a doping level of 1×10¹⁸ (1E18) to 8E18 atoms/cm³.

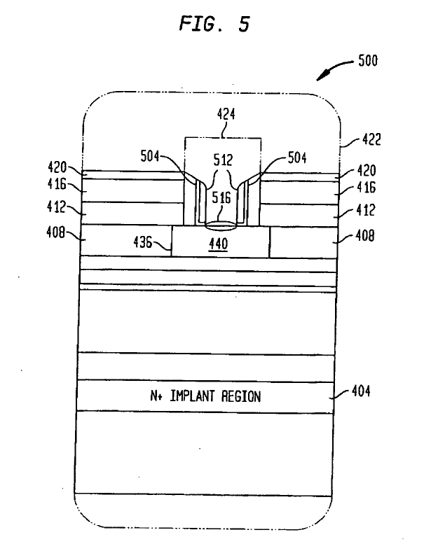

FIG. 5 illustrates a second exemplary CMOS/bipolar material cut-away magnified view 500 showing the material layers resulting from the second bipolar fabrication step 212 of FIG. 2 for the manufacture of the iJFET in accordance with an embodiment of the present invention. The second bipolar fabrication step 212 is characterized by a number of general steps. In section 422, a sidewall insulation layer 504, for example, a TEOS oxide layer, is deposited on the sidewall of the emitter window 424. The base layer segment 440 of the iJFET is advantageously counter-doped using, for example, phosphorus or arsenic to advantageously reduce substantially the 1E18 boron doping level of the base layer segment 440 to about a 1E16 to 5E17 atoms/cm³ doping level. A uniform doping profile is not as critical as having an average doping level that is sufficiently reduced to allow the base to be pinched-off. An average doping level range of 1E16 to 5E17 is an illustrative example. It is appreciated that doping levels and counter-doping levels can be adjusted, for example, according to the thickness of the base region. The doping level is also chosen to not cause channel block or degrade device performance. Variations in the doping level may still provide acceptable performance depending upon the application and these variations are considered within the scope of this invention. Another sidewall insulation layer 512 deposition follows, for example, a silicon nitride or silicon oxy-nitride, layer is deposited on the sidewall of the emitter window 424. A contact area 516 is then opened by an etching step using conventional chemistries in preparation for further processing.

An alternative method of manufacturing a base layer segment 440 with the proper doping concentration may be obtained by decreasing the thickness of the base layer segment 440. In another embodiment, bipolar transistor performance of other bipolar devices on the chip may be sacrificed by eliminating the counter-doping step and growing a base layer with a doping concentration in the range 1E16 to 5E17 atoms/cm³ level compared to the 1E18 boron doping level that is generally used in bipolar device fabrication.

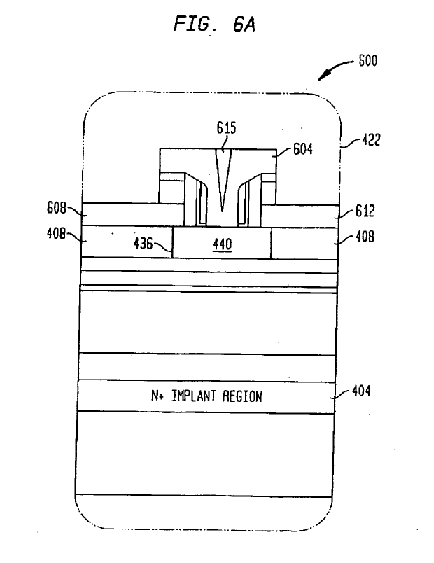

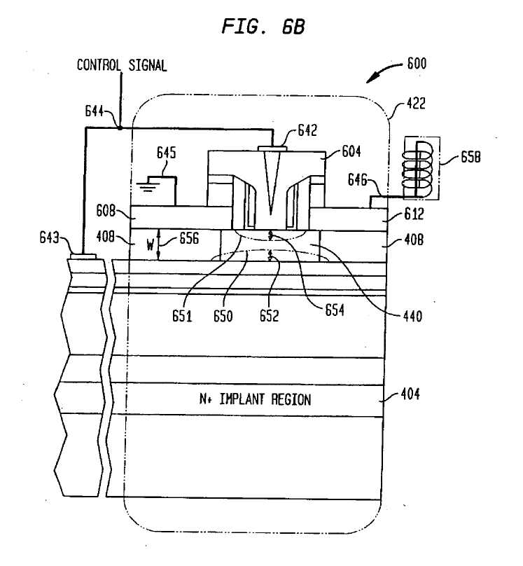

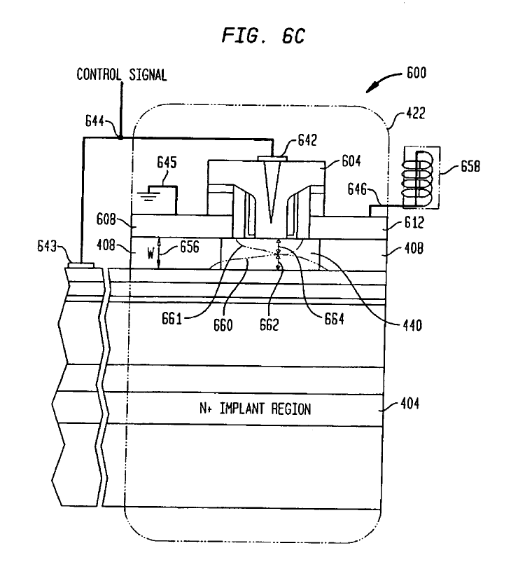

FIG. 6A illustrates a third exemplary CMOS/bipolar material cut-away magnified view of the iJFET device 600 showing the material layers resulting from the third bipolar fabrication step 216 of FIG. 2 for the manufacture of the iJFET in accordance with an embodiment of the present invention. The third bipolar fabrication step 216 is characterized by a number of general steps. In section 422, a polysilicon (poly) gate patterning, consisting of masking, etching, and deposition steps, is used to form the gate poly 604. A poly patterning step is used to form the source region 608 and drain region 612. A tungsten plug 615 is used to enhance connectivity of the gate poly 604.

FIG. 6B illustrates the iJFET device 600 with exemplary connections 642-646 and no bias depletion regions 650 and 651 in accordance with the present invention. A control signal 644 is connected to gate poly 604 at a connection point 642 and to second gate connection point 643. The source region 608 is connected to ground 645 and the drain region 612 is connected by a connecting path 646 to a transducer 658, such as a read/write head in a digital storage system, that is to be protected from ESD. With the control signal 644 at zero volts, no bias is applied to the iJFET device 600 and depletion regions 650 and 651 of widths w₁ 652 and w₂ 654, respectively, exist in the base layer segment 440 of width W 656. With no bias, w₁+w₂<W and a conduction channel exists between the source region 608 and the drain region 612 allowing charge to bleed off the transducer 658.

FIG. 6C illustrates the iJFET device 600 with exemplary connections 642-646 and biased depletion regions 660 and 661 in accordance with the present invention. The control signal 644 at an active control voltage level provides a bias to the iJFET device 600 and depletion regions 650 and 651 of FIG. 6B have grown in size to depletion regions 660 and 661 of widths w′₁ 662 and w′₂ 664, respectively. With the bias applied by the control signal 644, w′₁+w′₂>W and the conduction channel is pinched-off between the source region 608 and the drain region 612, which represents the state when the transducer 658 is in an operational state. With the base region pinched-off, the current between the drain contact and the source contact is essentially turned off.

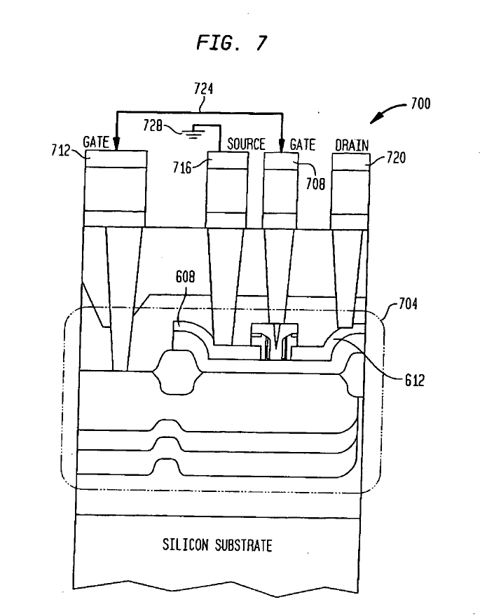

FIG. 7 illustrates a fourth exemplary CMOS/bipolar material cut-away view 700 showing the material layers resulting from the second CMOS fabrication step 220 of FIG. 2 for the manufacture of an iJFET 704 in accordance with an embodiment of the present invention. The second CMOS fabrication step 220 is characterized by a number of general steps. A source drain implant prepares the source polysilicon lead 608 and drain polysilicon lead 612 for metallization steps. A dielectric material is deposited with a contact window mask and etch steps providing access to the iJFET 704. A chemical mechanical planarization (CMP) step then is used to prepare the surface for metallization. Following CMP, a metallization process according to a chip netlist is followed providing metal first gate contact 708, second gate contact 712, source contact 716, and drain contact 720 of the iJFET 704. An advantageous connection 724 is provided to connect the first gate contact 708 to the second gate contact 712. Source contact 716 is connected to ground 728. The drain contact 720 may be connected to a signal, such as, the preamplifier signal 120 of FIG. 1A internal to the preamplifier chip 108. Alternatively, the drain contact 720 may be connected to an external device contact, such as, source contact 160 of FIG. 1B, when the iJFET 704 is used as a discrete iJFET, such as the discrete iJFET 156 of FIG. 1B. In a preferred embodiment, the first gate contact 708 and the second gate contact 712 are connected together to pinch-off the channel in the base region of the iJFET when a bias is applied to the gate. However, in other embodiments, one side, such as the first gate contact 708, may be tied up to a fixed voltage, and the other gate, such as, the second gate contact 712 may be connected to a variable voltage. A passivation step is used to protect the on-chip devices. After passivation, the CMOS bipolar device fabrication process 200 ends.

While the present invention has been disclosed in a presently preferred context, it will be recognized that the present teachings may be adapted to a variety of contexts consistent with this disclosure and the claims that follow. For example, the present invention is disclosed mainly in the context of an NPN type of device. It will be appreciated that it may also be employed with a PNP type of device. In the case of a PNP type device, an N-channel JFET device is formed. The resistive element is an N-bar sandwiched between two P-layers. The concepts of the invention as applied to the described NPN type iJFET apply to a PNP type iJFET. It will also be appreciated that variations in the particular hardware and manufacturing steps employed are feasible, and to be expected as both evolve with time. For example, it is possible that variations in insulation/isolation steps, masking, etching, and other such manufacturing steps as generally described herein can be expected as technology processes change and new technology processes are developed. Other such modifications and adaptations to suit a particular design application will be apparent to those of ordinary skill in the art.

We claim:

1. A semiconductor device comprising:
a silicon substrate with a buried implant region;
a base region located over the buried implant region, the base region doped to have a dopant level sufficiently reduced to allow the base region to be pinched-off upon application of a first gate voltage;
a source lead in contact with the base region;
a drain lead in contact with the base region and spaced apart from the source lead;
a gate region placed over the base region between the source lead and the drain lead, apart from the source lead and the drain lead, and in contact with the base region; and
a gate lead in contact with the buried implant region and in contact with the gate region, wherein with a second gate voltage applied to the gate lead a conduction channel is formed in the base region between the source lead and the drain lead and with the first gate voltage applied to the gate lead, depletion regions form in the base region that pinch-off the conduction channel between the source lead and the drain lead.

2. The semiconductor device of claim 1 wherein the base region is doped by counter-doping.

3. The semiconductor device of claim 1 wherein the dopant level is an average dopant level of about 1E16 to 5E17 atoms/cm³.

4. The semiconductor device of claim 1 wherein the base region is counter-doped from a substantially 1E18 dopant level to about a 1E16 to 5E17 atoms/cm³ dopant level.

5. The semiconductor device of claim 1 wherein the source lead is connected to ground and the drain lead is connected to a device for protecting the device from electrostatic discharge (ESD).

6. The semiconductor device of claim 5 wherein the gate voltage is provided by a control signal which provides the first gate voltage when ESD protection is not necessary and the second gate voltage when ESD protection is desired.

7. The semiconductor device of claim 1 wherein the dopant level is lower than the dopant level of a plurality of base regions of other semiconductor devices located on the silicon substrate.

8. The semiconductor device of claim 1 further comprising:
the gate lead in contact with the buried implant region separated from the connection with the base region, wherein the gate lead operates as a transistor collector lead;
an emitter lead in contact with the base region separate from the gate lead, wherein the emitter lead operates as a transistor emitter lead; and
a base lead connected to the source lead and connected to the drain lead, wherein the base lead operates as a transistor base lead.

9. A semiconductor device comprising:
a silicon substrate with an implanted collector region, the collector region having a first connection point;
a base region located over the buried implant region, the base region having a dopant level low enough to allow the base region to be pinched-off upon application of a first gate voltage;
a source connection point on the base region;
a drain connection point on the base region and spaced apart from the source connection point; and
a gate connection point on the base region, the gate connection point in contact with the first connection point and adapted for coupling to a control signal, the gate connection point being placed between the source connection point and the drain connection point, wherein with the control signal applying the first gate voltage, the gate region is pinched-off.

10. The semiconductor device of claim 9 wherein with the control signal applying a second gate voltage, a conduction channel is formed in the gate region between the source and drain connection points.

11. The semiconductor device of claim 9 wherein the semiconductor device is a bipolar transistor embedded in a complementary metal oxide semiconductor (CMOS) process.

12. The semiconductor device of claim 10 wherein the control signal is at the second gate voltage when ESD protection is selected or no power is supplied to a control circuit that generates the control signal.

13. The semiconductor device of claim 9 wherein the control signal is at the first gate voltage when ESD protection is not selected.

14. The semiconductor device of claim 11 wherein the semiconductor device is fabricated to act as a junction field effect transistor having a base region doped to about a 1E16 to 5E17 atoms/cm³ doping level with bipolar transistors on the chip having associated base regions doped to about a 1E18 doping level.

15. A method of manufacturing a semiconductor device comprising:
forming a buried implant region in a silicon substrate with a first connection point;
forming a base region over the buried implant region with a dopant level low enough to allow the base region to be pinched-off upon application of a first gate voltage;
forming a source connection point on the base region;
forming a drain connection point on the base region spaced apart from the source connection point; and
forming a gate connection point on the base region, the gate connection point in contact with the first connection point and adapted for coupling to a control signal, the gate connection point being placed on the base region between the source connection point and the drain connection point.

16. The method of claim 15 wherein the dopant level is about a 1E16 to 5E17 atoms/cm³.

17. The method of claim 15 further comprises:
doping the base region at a substantially 1E18 dopant level as part of the manufacture of conventional semiconductor devices located on the silicon substrate; and
counter-doping the base region to about a 1E16 to 5E17 atoms/cm³ dopant level.

18. The method of claim 15 further comprises:
applying on the control signal a first gate voltage to pinch-off the base region.

19. The method of claim 15 further comprises:
applying on the control signal a second gate voltage, whereby a conduction path is formed in the base region between the drain connection point and the source connection point.

20. The method of claim 15 further comprises:
applying on the control signal a second gate voltage, whereby the semiconductor device operates as a junction field effect transistor (JFET) with low resistance between the drain connection point and the source connection point.
